(19) United States
(12) Patent Application Publication
(10) Pub. No.: US 2010/0023847 A1
(43) Pub. Date: Jan. 28, 2010

(54) Storage Subsystem and Method for Verifying Data Using the Same

(75) Inventors: Seiki Morita, Odawara (JP); Junji Ogawa, Sagamihara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/236,532

(22) Filed: Sep. 24, 2008

(30) Foreign Application Priority Data
Jul. 28, 2008 (JP) 2008-194063

(51) Int. Cl. H03M 13/09; G06F 11/07

(52) U.S. Cl. 714/801; 714/E11.024

(57) ABSTRACT

A subject of the invention is to propose a storage subsystem assuring high reliability and not impairing processing performance. The invention is a storage subsystem which includes a storage device including a hard disk drive and a controller for controlling an access to the storage device in response to a predetermined access command transmitted from a host computer. The storage subsystem stores, in response to a write request transmitted from the host computer, data associated with the write request together with its parity in the storage device as well as verifies the validity of the data stored in the storage device independently of a response to the write request and, when there is an abnormality in the data, repairs the abnormal data.

### CROSS REFERENCES TO RELATED APPLICATIONS

This application relates to and claims priority from Japanese Patent Application No. 2008-194063, field on Jul. 28, 2008, the entire disclosure of which is incorporated herein by reference.

### BACKGROUND OF THE INVENTION

1. Field of the Invention

The present invention relates to a storage subsystem and more particularly to a technique for verifying data written into a hard disk drive of a storage subsystem.

2. Description of Related Art

A Hard disk drive of SATA system (hereinafter referred to as a “SATA drive”) sacrifices consideration for the selection of parts and materials, machining accuracy, evaluation period or the like during the manufacturing step, thereby intending to increase its capacity and reduce its price. Accordingly, the SATA drive has a higher possibility to cause an error at the time of writing (for example, “skipping of writing”, “writing to an unsuitable position”, “off-track write” or the like) compared with a hard disk drive of SAS system (hereinafter referred to as a “SAS drive”) or a hard disk drive of Fibre Channel system (hereinafter referred to as an “FC drive”) and is not generally considered to be fit for application to storage products for which high reliability is demanded. On the other hand, it is necessary to improve reliability for the SATA drive in order to realize an increase in capacity and reduction in price of the storage products.

Therefore, a technique for improving the reliability for a storage subsystem using the SATA drive has been proposed as disclosed in, for example, JP-A-2007-128527 (Patent Document 1). That is, Patent Document 1 discloses a technique in which a controller of a storage device writes data into a hard disk drive in response to a write request from a host system as sell as reads out the written data immediately and compares the read data with data cached in accordance with the write request for verifying the validity of the data written into the hard disk drive.

### SUMMARY OF THE INVENTION

In Patent Document 1, since verification by reading out data is performed along with writing of data, high reliability can be assured. On the other hand, the load on the controller or the SATA drive is high, so that the technique is insufficient in terms of processing performance. Therefore, such a storage subsystem can sufficiently meet the requirement of a user who attaches importance to high reliability, whereas it cannot sufficiently meet the requirement of a user who attaches importance to high processing performance. On the other hand, a storage subsystem of high capacity and low price is desired due to the expansion of data capacity owing to the development of information system.

Therefore, the invention intends to provide a storage subsystem of high capacity and low price.

More specifically, an object of the invention is to propose a storage subsystem assuring reliability and not impairing processing performance even when a hard disk drive of relatively low reliability such as the SATA drive is used.

In order to solve the above subject, the invention is a storage subsystem which stores, in response to a write request transmitted from a host computer, data associated with the write request together with its parity into a hard disk drive as well as verifies the validity of the data stored into the hard disk drive independently of a response to the write request.

That is, according to an aspect, the invention is a storage subsystem which includes a storage device formed with at least one virtual device based on at least one hard disk drive and a controller connected to the storage device for controlling an access to a corresponding virtual device of the storage device in response to a predetermined access command transmitted from a host computer. The controller calculates, in response to a write command transmitted from the host computer, at least one parity based on a data segment associated with the write command and stores a data set including the data segment and the calculated at least one parity into storage areas in the virtual device in a striping fashion. Further, the controller performs a parity check processing which reads out the data set from the storage areas in the virtual device, calculates at least one parity for verification based on a data segment in the read data set and determines, based on the calculated at least one parity for verification and the at least one parity in the read data set, whether or not there is an abnormality in consistency of the at least one parity.

According to another aspect, the invention is a storage subsystem which includes a storage device formed with at least one virtual device based on at least one hard disk drive and a controller connected to the storage device for controlling an access to a corresponding virtual device of the storage device in response to a predetermined access command transmitted from a host computer. The controller calculates, in response to a write command transmitted from the host computer, at least one parity based on a data segment associated with the write command and stores a data set including the data segment and the calculated at least one parity into storage areas in the virtual device in a striping fashion. When a first data verification mode is set for an access object designated by the write command, the controller performs a first data verification processing for verifying a data segment stored in a storage area in the virtual device at the time of response to the write command, and when a second data verification mode is set for the access object designated by the write command, the controller performs a second data verification processing for verifying the data segment stored in the storage area in the virtual device independently of a response to the write command.

According to still another aspect, the invention is a method for verifying data in a storage subsystem including a storage device formed with at least one virtual device based on at least one hard disk drive and a controller connected to the storage device for controlling an access to a corresponding virtual device of the storage device in response to a predetermined access command transmitted from a host computer. The method for verifying data includes the steps of: receiving, by the controller, a write command transmitted from the host computer; calculating, by the controller, in response to the received write command, at least one parity based on a data segment associated with the write command and storing a data set including the data segment and the calculated at least one parity into storage areas in the virtual device in a striping fashion; and performing, by the controller, a parity check processing which reads out the data set from the storage areas in the virtual device independently of a response to the write command, calculates at least one parity for verification based on the data segment in the read data set and determines, based on the calculated at least one parity for verification and the at least one parity in the read data set, whether or not there is an abnormality in consistency of the at least one parity.

According to the invention, a storage device assuring reliability and having high processing performance is provided.

Other technical features and advantages of the invention will be apparent from the following embodiment to be described with reference to the accompanying drawings. The invention can be widely applied to a storage subsystem or the like which ensures the reliability of data using parity.

### BRIEF DESCRIPTION OF THE DRAWINGS

FIG. 1 is a diagram for explaining an overall configuration of a storage subsystem in an embodiment to which the invention is applied;

FIG. 2 is a diagram showing an example of content of a memory unit of a controller in an embodiment to which the invention is applied;

FIG. 3 is a diagram showing an example of a drive management table of a controller in an embodiment to which the invention is applied;

FIG. 4 is a diagram showing an example of a logical unit management table of a controller in an embodiment to which the invention is applied;

FIG. 5 is a diagram showing an example of an update data management table of a controller in an embodiment to which the invention is applied;

FIG. 6 is a diagram showing an example of a data verification mode definition table of a controller in an embodiment to which the invention is applied;

FIG. 7 is a diagram showing an example of a drive failure management table of a controller in an embodiment to which the invention is applied;

FIG. 8 is a diagram showing an example of a data verification mode definition window displayed on a user interface of a management console in an embodiment to which the invention is applied;

FIG. 9 is a diagram for explaining a RAID configuration of a storage device in an embodiment to which the invention is applied;

FIG. 10 is a conceptual diagram for explaining a write and compare processing by a controller in an embodiment to which the invention is applied;

FIG. 11 is a conceptual diagram for explaining a parity check processing by a controller in an embodiment to which the invention is applied;

FIG. 12 is a flowchart for explaining a data write processing by a controller in an embodiment to which the invention is applied;

FIG. 13 is a flowchart for explaining an access pattern check processing by a controller in an embodiment to which the invention is applied;

FIG. 14 is a flowchart for explaining a write and compare processing by a controller in an embodiment to which the invention is applied;

FIG. 15 is a flowchart for explaining an update data check processing by a controller in an embodiment to which the invention is applied;

FIG. 16 is a diagram showing the transition of content of an update data management table of a controller in an embodiment to which the invention is applied;

FIG. 17 is a flowchart for explaining a parity check processing by a controller in an embodiment to which the invention is applied;

FIG. 18 is a flowchart for explaining a read processing by a controller in an embodiment to which the invention is applied;

FIG. 19 is a diagram showing an example of a data verification mode definition table of a controller in an embodiment to which the invention is applied; and

FIG. 20 is a flowchart for explaining a read processing by a controller in an embodiment to which the invention is applied.

### DESCRIPTION OF THE PREFERRED EMBODIMENT

The invention is a storage subsystem which stores, in response to a write request transmitted from a host computer, data associated with the write request into a hard disk drive together with its parity under RAID control as well as verifies the validity of the data stored in the hard disk drive in, for example, the background or at the time of response to a read request independently of a response to the write request.

In the following, an embodiment of the invention will be described with reference to the drawings.

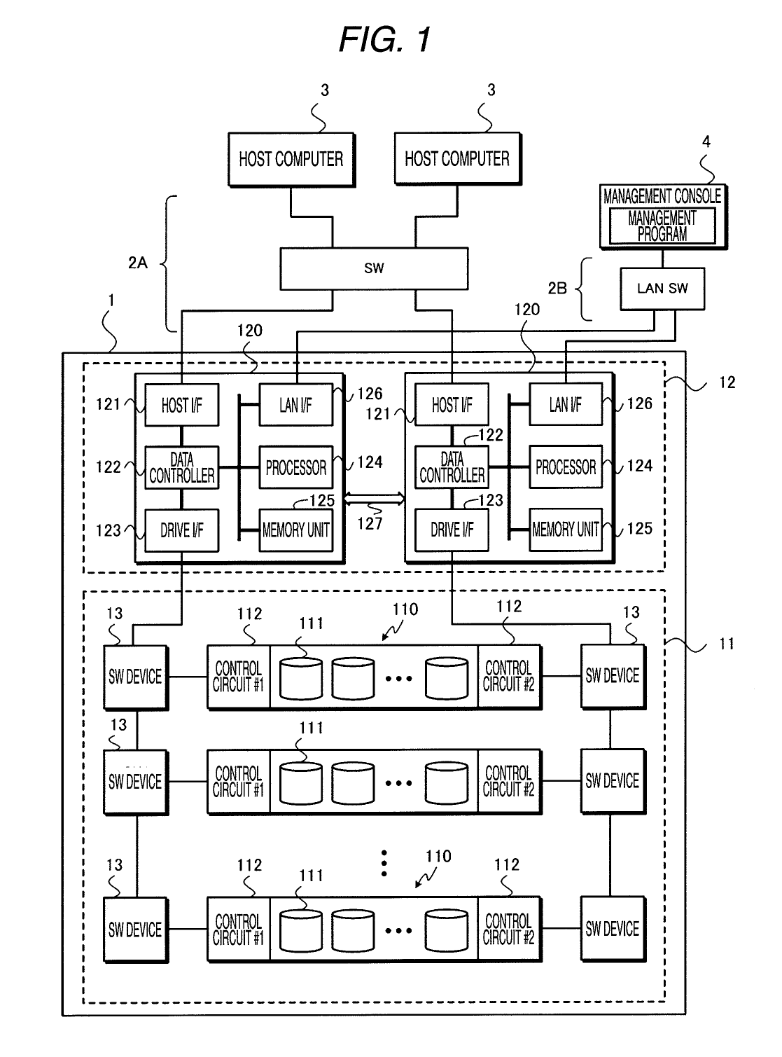

FIG. 1 is a diagram for explaining an overall configuration of a storage subsystem according to an embodiment of the invention. A storage subsystem 1 shown in FIG. 1 is connected to host computers 3 via a network 2A to form a computer system. The storage subsystem 1 is also connected to a management console 4 via a management network 2B.

As the network 2A, for example, any one of LAN, Internet and SAN (Storage Area Network) can be used. Typically, the network 2A includes a network switch, a hub or the like. In the embodiment, the network 2A is a SAN (FC-SAN) using a fibre channel protocol, and the management network 2B is a LAN based on TCP/IP.

The host computer 3 includes a processor, a main memory, a communication interface and a hardware resource such as a local input/output device as well as includes a software resource such as a device driver, an operating system (OS) and an application program (not illustrated). With this configuration, the host computer 3 executes various kinds of application programs under the control of the processor to perform a desired processing while accessing the storage subsystem 1 through the cooperation with the hardware resource.

The storage subsystem 1 is a storage device for supplying a data storage service to the host computer 3. The storage subsystem 1 includes a storage device 11 including a memory medium for storing data and a controller 12 for controlling the storage device. The storage device 11 and the controller 12 are connected to each other via a disk channel. An internal hardware configuration of the controller 12 is duplicated, so that the controller 12 can access the storage device 11 via two channels (connection paths).

The storage device 11 includes at least one drive unit 110. For example, the drive unit 110 includes hard disk drives 111 and control circuits 112 for controlling driving of the hard disk drives 111. For example, the hard disk drive 111 is fitted into a chassis of the drive unit 110, thereby being implemented. A solid state device (SSD) such as a flash memory may be used instead of the hard disk drive 111. The control circuit 112 is also duplicated corresponding to the duplicated path configuration in the controller 12. A SATA drive, for example, is employed for the hard disk drive 111. This does not mean, however, that a SAS drive or an FC drive is excluded. Further, drives of various formats are allowed to coexist by using the following switching device 13. The storage device 11 is also referred to as a disk array.

The drive unit 110 is typically connected to the controller 12 via the switching device (expander) 13. The plurality of drive units 110 can be connected with one another in various forms by using the plurality of switching devices 13. In the embodiment, the drive unit 110 is connected to each of the plurality of switching devices 13 connected in a column. Specifically, the controller 12 accesses the drive unit 110 via the at least one switching device 13 connected in a column under the control of the controller 12. Accordingly, the drive unit 110 can be easily expanded by additionally connecting the switching device 13 in a column. Therefore, the storage capacity of the storage subsystem 1 can be easily expanded.

The hard disk drives 111 in the drive unit 110 typically form a RAID group based on a predetermined RAID configuration (for example, RAID 6) and are accessed under the RAID control. For example, the RAID control is performed by a known RAID controller or a RAID engine (not illustrated) implemented on the controller 12. The RAID group may be configured by the hard disk drives 111 only in one drive unit 110 or may be configured by the hard disk drives 111 over the plurality of drive units 110. The hard disk drives 111 belonging to the same RAID group are handled as a virtual logical device (virtual device).

The controller 12 is a system component for controlling the entire storage subsystem 1. A main role thereof is to execute an I/O processing on the storage device 11 based on an I/O access request (I/O command) from the host computer 3. Further, the controller 12 in the embodiment verifies the validity of data written into the hard disk drive 111 synchronously or asynchronously. The controller 12 executes processing regarding the management of the storage subsystem 1 based on various requests from the management console 4.

As described above, the components in the controller 12 are duplicated in the embodiment in terms of fault tolerance. Hereinafter, the controller 12 is referred to as a “controller 120” when it means a duplicated individual controller 12.

Each of the controllers 120 includes a host interface (host I/F) 121, a data controller 122, a drive interface (drive I/F) 123, a processor 124, a memory unit 125 and a LAN interface 126. The controllers 120 are connected to each other via a bus 127 so as to communicate with each other.

The host interface 121 is an interface for connecting to the host computer 3 via the network 2A, controlling a data communication between the host interface 121 and the host computer 3 in accordance with a predetermined protocol. For example, when receiving a write request (write command) from the host computer 3, the host interface 121 writes the write command and data associated with the same into the memory unit 125 via the data controller 122. The host interface 121 is also referred to as a channel adapter or a front-end interface.

The data controller 122 is an interface between the components in the controller 120, controlling transmission and reception of data between the components.

The drive interface 123 is an interface for connecting to the drive unit 110, controlling a data communication between the drive interface 123 and the drive unit 110 in accordance with a predetermined protocol according to an I/O command from the host computer 3. That is, when periodically checking the memory unit 125 to find data associated with an I/O command from the host computer 3 on the memory unit 125, the processor 124 uses the drive interface 123 to access the drive unit 110.

More specifically, for example, when finding data associated with a write command on the memory unit 125, the drive interface 123 accesses the storage device 11 in order to destage the data on the memory unit 125 designated by the write command to the storage device 11 (that is, a predetermined storage area on the hard disk drive 111). Further, when finding a read command on the memory unit 125, the drive interface 123 accesses the storage device 11 in order to stage data on the storage device 11 designated by the read command to the memory unit 125. The drive interface 123 is also referred to as a disk adapter or a back-end interface.

The processor 124 executes various kinds of control programs loaded on the memory unit 125 to control an operation of the entire controller 120 (that is, the storage subsystem 1). The processor 124 may be of the multi-core type.

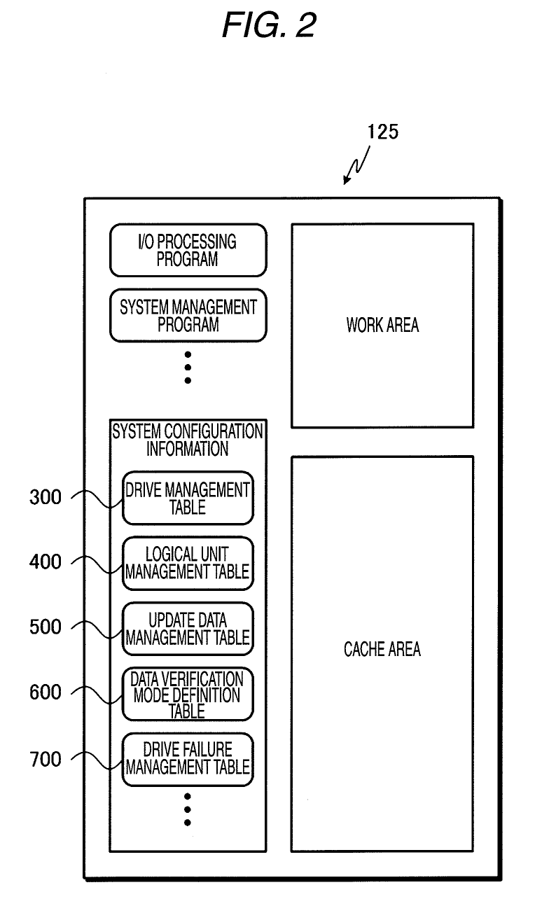

The memory unit 125 functions as a main memory of the processor 124 as well as functions as a cache memory of the channel adapter 121 and the drive interface 123. For example, the memory unit 125 includes a volatile memory such as a DRAM or a non-volatile memory such as a flash memory. The memory unit 125 stores system configuration information of the storage subsystem 1 itself as shown in FIG. 2, for example. The system configuration information is information necessary for operating the storage subsystem 1, including logical volume configuration information and RAID configuration information, for example. In an example shown in FIG. 2, the memory unit 125 holds a drive management table 300, a logical unit management table 400, an update data management table 500, a data verification mode definition table 600 and a drive failure management table 800 as part of the system configuration information. When the power is applied to the storage subsystem 1, for example, the system configuration information is read out from a specific storage area on the hard disk drive 111 in accordance with an initial sequence under the control of the processor 124 and loaded on a predetermined area in the memory unit 125.

The LAN interface 126 is an interface circuit for connecting to the management console 4 via a LAN. As the LAN interface, for example, a network board in accordance with TCP/IP and Ethernet (registered trademark) can be employed.

The management console 4 is a terminal console for a system administrator to manage the entire storage subsystem 1 and is typically a general-purpose computer in which a management program is implemented. The management console 4 is also referred to as a service processor (SVP). In FIG. 1, although the management console 4 is disposed outside of the storage subsystem 1 via the management network 2B, the configuration is not limited thereto. The management console 4 may be disposed inside of the storage subsystem 1. Alternatively, the controller 12 may be configured so as to include a function equivalent to the management console 4.

The system administrator gives the controller 12 a command via a user interface provided by the management console 4. With this command, the system administrator can acquire and refer to the system configuration information of the storage subsystem 1 or configure and change the system configuration information. For example, the system administrator operates the management console 4 to configure a logical volume or virtual volume and configure the RAID configuration along with the expansion of hard disk drive. Typically, when the management console 4 gives one of the controllers 120 a command of configuration, the configuration is transmitted to the other controller 120 via the bus 127 to be reflected.

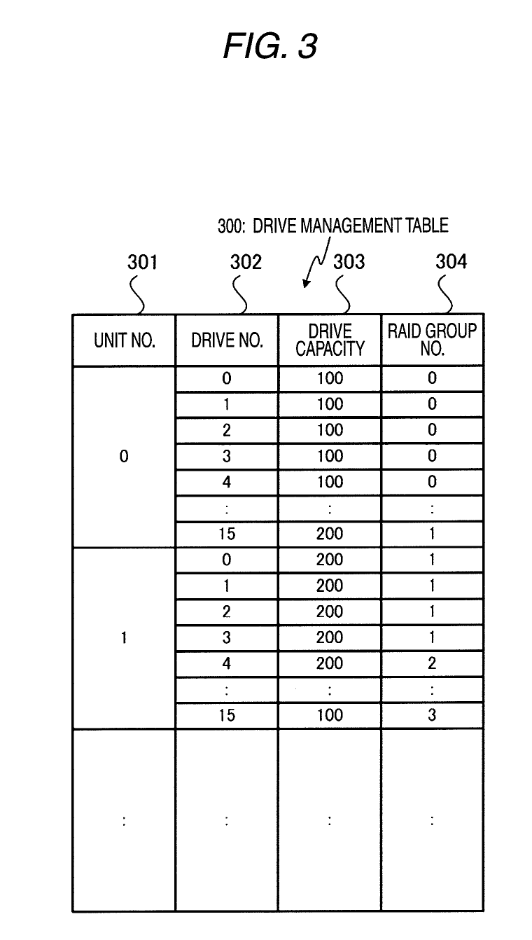

FIG. 3 is a diagram showing an example of the drive management table 300 in the controller 12 according to an embodiment of the invention.

The drive management table 300 is a table for managing the hard disk drives 111 accommodated in the drive unit 110. As shown in FIG. 3, the drive management table 300 includes each of columns of unit No. 301, drive No. 302, drive capacity 303 and RAID group No. 304.

The unit No. 301 is a number for uniquely identifying each of the drive units 110, and the drive No. 302 is a number for uniquely identifying each of the hard disk drives 111 accommodated in the drive unit 110. The drive capacity 303 is a designed storage capacity of the relevant hard disk drive 111. The RAID group No. 304 is a number of RAID group to which the relevant hard disk drive 111 belongs. One RAID group can be assumed as one virtual device. At least one logical unit is formed in each RAID group.

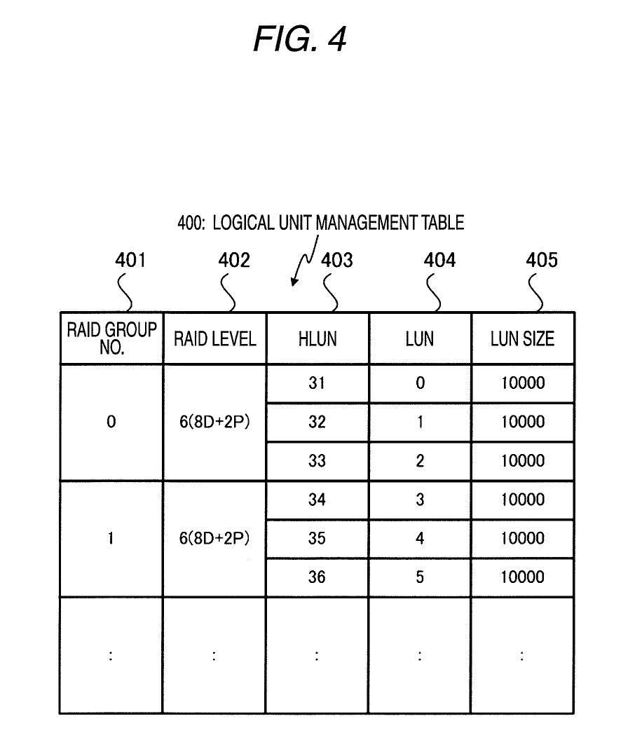

FIG. 4 is a diagram showing an example of the logical unit management table 400 in the controller 12 according to an embodiment of the invention.

The logical unit management table 400 is a table for managing the logical unit formed in each RAID group. As shown in FIG. 4, the logical unit management table 400 includes each of columns of RAID group No. 401, RAID level 402, host logical unit No. (HLUN) 403, logical unit No. 404 and logical unit size 405.

The RAID group No. 401 is a number for uniquely identifying each RAID group. The RAID group No. 401 corresponds to the RAID group No. 304 in the drive management table 300 shown in FIG. 3. The RAID level 402 shows a RAID level (RAID configuration) of the relevant RAID group. For example, RAID group #0 is configured by RAID 6(8D+2P). The host logical unit No. 403 is a number of logical unit used by the host computer 3. The logical unit No. 404 is a number for uniquely identifying each logical unit (hereinafter also referred to as an “internal logical unit”) in the storage device 11. For example, logical unit #32 used by the host computer 3 is associated with internal logical unit #0 formed in the RAID group #0. The logical unit size 405 shows a storage capacity of the relevant logical unit.

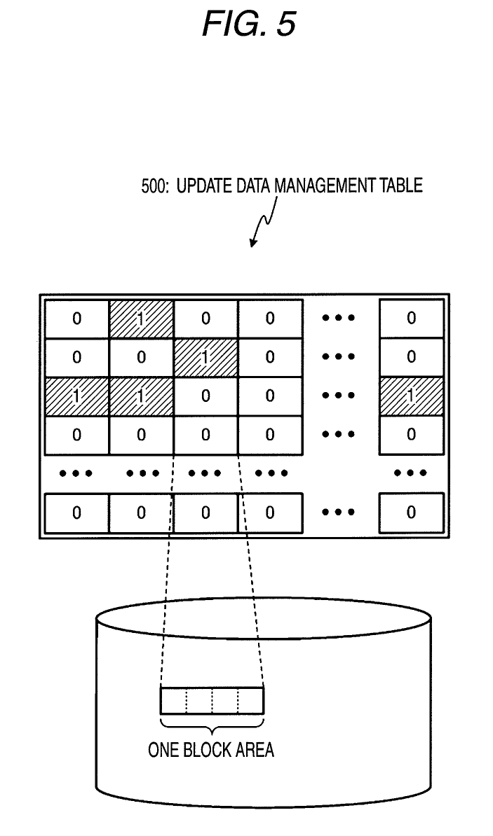

FIG. 5 is a diagram showing an example of the update data management table 500 in the controller 12 according to an embodiment of the invention.

The update data management table 500 is a table for managing whether or not data stored in a specific storage area on the hard disk drive 111 has been updated and typically a table of a bit map structure. For example, with a predetermined number of storage areas being as one block area (management area), the update data management table 500 is used for checking whether or not data has been updated for each block area by associating a cell (bit) with each of the block areas. Typically, four consecutive storage areas are defined as one block area. When data has been updated in any of storage areas in one block area, the value of a cell in the update data management table 500 corresponding to the relevant block area is set to “1” (flag of cell is turned ON).

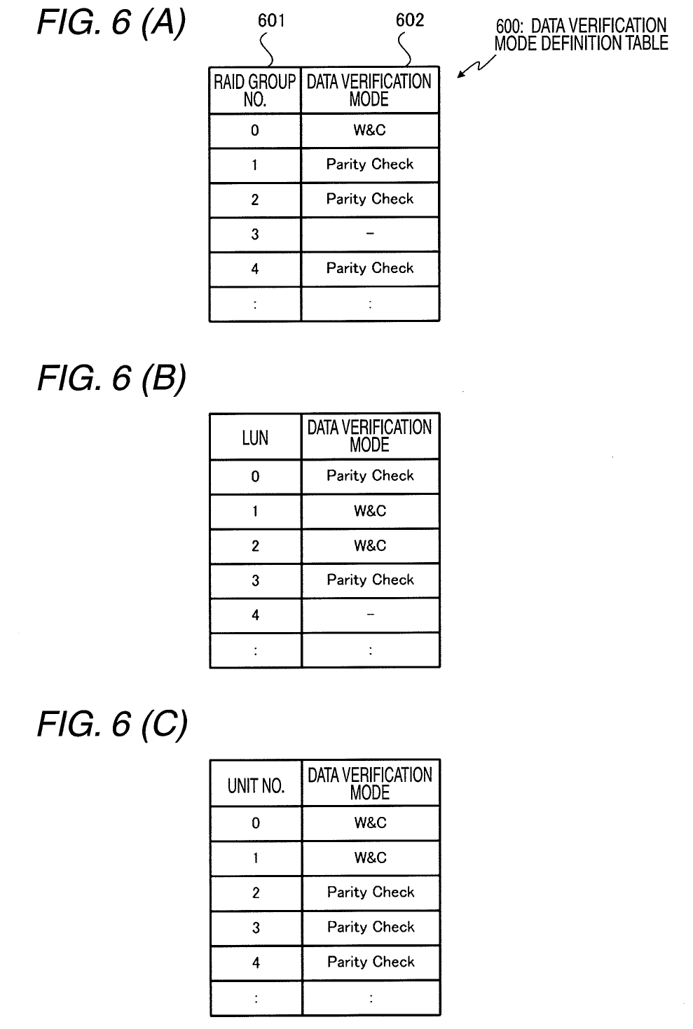

FIGS. 6A to 6C are diagrams showing examples of the data verification mode definition table 600 in the controller 12 according to an embodiment of the invention.

The data verification mode definition table 600 is a table for defining which data verification mode is used for performing a verification processing on data stored in the hard disk drive 111. The data verification processing can be performed in accordance with various partitioned objects.

That is, the data verification mode definition table 600 shown in FIG. 6A is a table in which the data verification mode is designated in RAID group, including each of columns of RAID group No. 601 and data verification mode 602. In the embodiment, a write and compare mode, a parity check mode and a normal mode are prepared as the data verification mode 602. According to the example shown in FIG. 6A, the write and compare mode is designated in the RAID group #0, and the parity check mode is designated in the RAID group #1. The normal mode is designated in the RAID group #3.

Further, in the data verification mode definition table 600 shown in FIG. 6B, the data verification mode 602 is designated in logical unit. In the data verification mode definition table 600 shown in FIG. 6C, the data verification mode 602 is designated in unit.

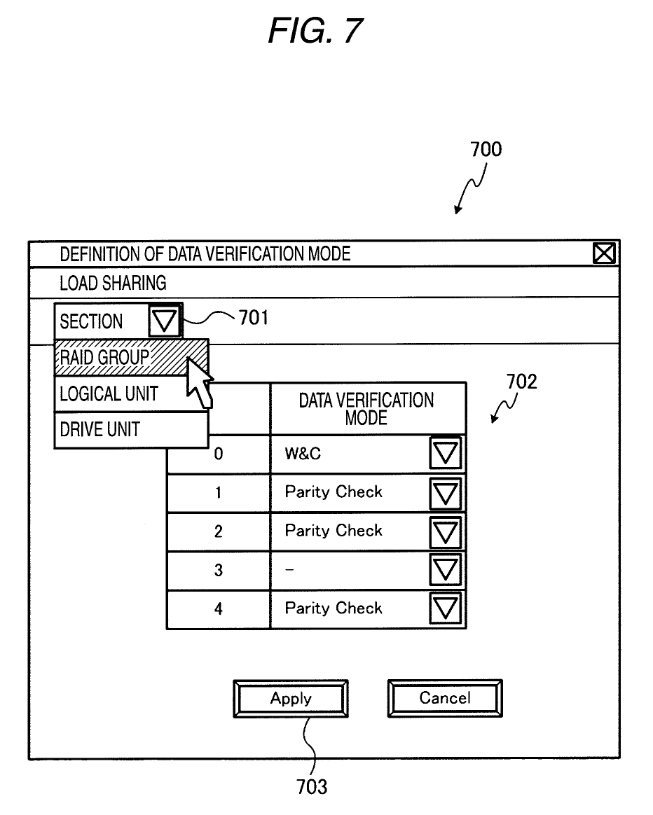

Prior to operation of the storage subsystem, the system administrator defines the content of the data verification mode definition table 600 via the management console 4. FIG. 7 shows a data verification mode definition window on a user interface of the management console 4. The system administrator selects an object to which the data verification mode is applied in a section menu 701 of a data verification mode definition window 700. After selecting the data verification mode for each entry of a data verification mode definition field 702, the system administrator selects an apply button 703. In response to this, the management console 4 notifies the set content of the controller 12, and the controller 12 updates the data verification mode definition stable 600.

In the following, a description will be made based on the data verification mode definition table 600 in which the data verification mode is designated in RAID group.

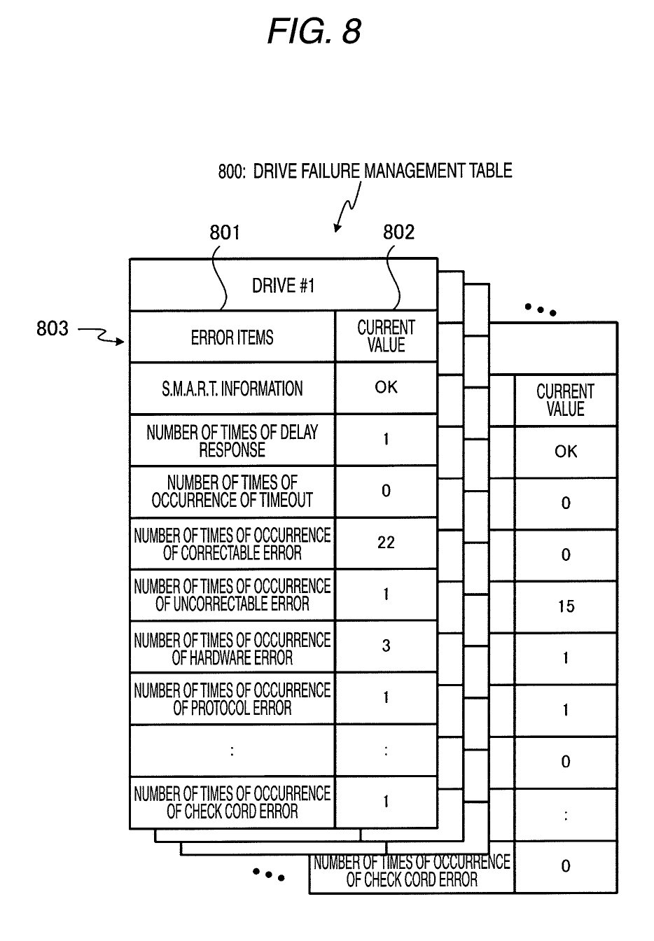

FIG. 8 is a diagram showing an example of the drive failure management table 800 in the controller 12 according to an embodiment of the invention.

The drive failure management table 800 is a table for managing a failure occurrence condition in each of the hard disk drives 111. As shown in FIG. 8, the drive failure management table 800 includes a plurality of entries 803 including error items 801 and current value 802. For example, the error items 801 include S.M.A.R.T. information, the number of times of delay response, the number of times of occurrence of timeout, the number of times of correctable error, the number of times of uncorrectable error, the number of times of occurrence of hardware error, the number of times of occurrence of protocol error and the number of times of occurrence of check cord error. The controller 12 collects information regarding the error items 801 by accessing the hard disk drives 111 or by an error report from the hard disk drives 111 and updates the drive failure management table 800 to monitor the frequency of failure occurrence. Each of the error items 801 has a permissible value (not illustrated). When the current value of any of entries in the drive failure management table 800 exceeds the permissible value, the controller 12 recognizes that the relevant hard disk drive 111 tends to suffer from frequent failures.

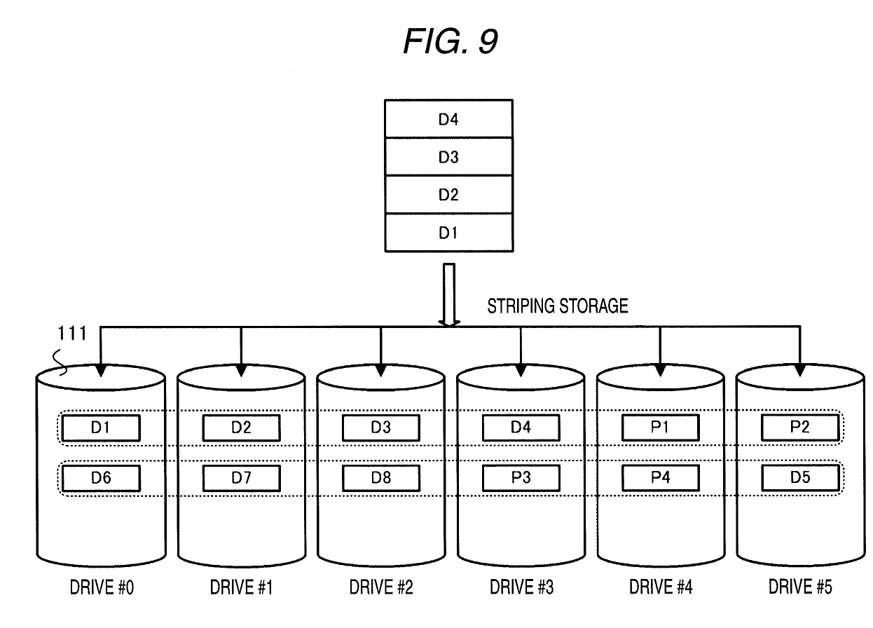

FIG. 9 is a diagram for explaining a RAID configuration in a storage device according to an embodiment of the invention.

As described above, in the embodiment, the plurality of hard disk drives 111 form at least one RAID group (virtual device) which is typically configured by RAID 6. RAID 6 is a technique for writing data associated with a write command into the plurality of hard disk drives 111 forming the same RAID group while dispersively distributing (dispersively striping) the data together with two error correcting code data or parity data (hereinafter referred to as “parity”). It is assumed that the RAID group in the embodiment is configured by RAID 6. However, it may be configured by other RAID levels utilizing parity, for example, RAID 4 or RAID 5.

In the example shown in FIG. 9, in response to a write command for requesting writing of data segments D1 to D4, first and second parities P1 and P2 are calculated, and the data segments D1 to D4 and the first and second parities P1 and P2 are dispersively stored in the plurality of hard disk drives 111. A data set including such data segments and these parities is referred to as a parity group herein. In response to update from the data segment D1 to a data segment D_New, first and second parities P1_New and P2_New are recalculated in a parity group to which the data segment D1 belongs.

The verification of data stored in the hard disk drives 111 is performed by reading out a parity group including a data segment to be verified from the hard disk drives 111, recalculating the first and second parities P1 and P2 based on the data segments D1 to D4 in the read parity group and comparing the read first and second parities P1 and P2 with the recalculated first and second parities P1 and P2.

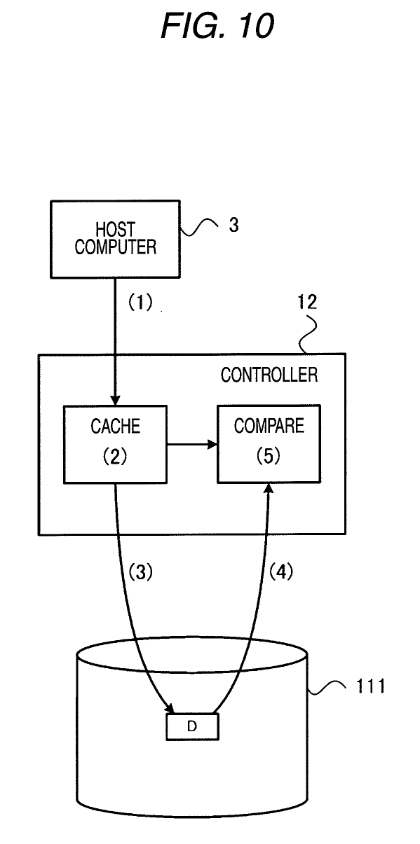

FIG. 10 is a conceptual diagram for explaining a write and compare processing by the controller 12 according to an embodiment of the invention. The write and compare processing is a processing for verifying the validity of data by comparing data before and after writing at the time of writing of data due to a write command. The write and compare processing can be incorporated into part of the data verification technique of the invention. In the embodiment, the controller 12 performs a data verification due to the write and compare processing when the data verification mode is not set to the parity check mode.

That is, as shown in FIG. 10, when receiving a write command from the host computer 3 ((1) in FIG. 10), the controller 12 of the storage subsystem 1 writes data associated with the write command into a cache area in the memory unit 125 ((2) in FIG. 10). The controller 12 typically transmits a write completion response to the host computer 3 at the time of cashing data. Next, the controller 12 stores the cached data in a predetermined storage area on the hard disk drive 111 under the RAID control ((3) in FIG. 10) as well as reads out the just stored data from the hard disk drive 111 ((4) in FIG. 10). The controller 12 then compares the cached data with the read data to determine whether or not they coincide with each other ((5) in FIG. 10). As a result, when determining that they do not coincide with each other, the controller 12 transmits a data writing failure response to the host computer 3.

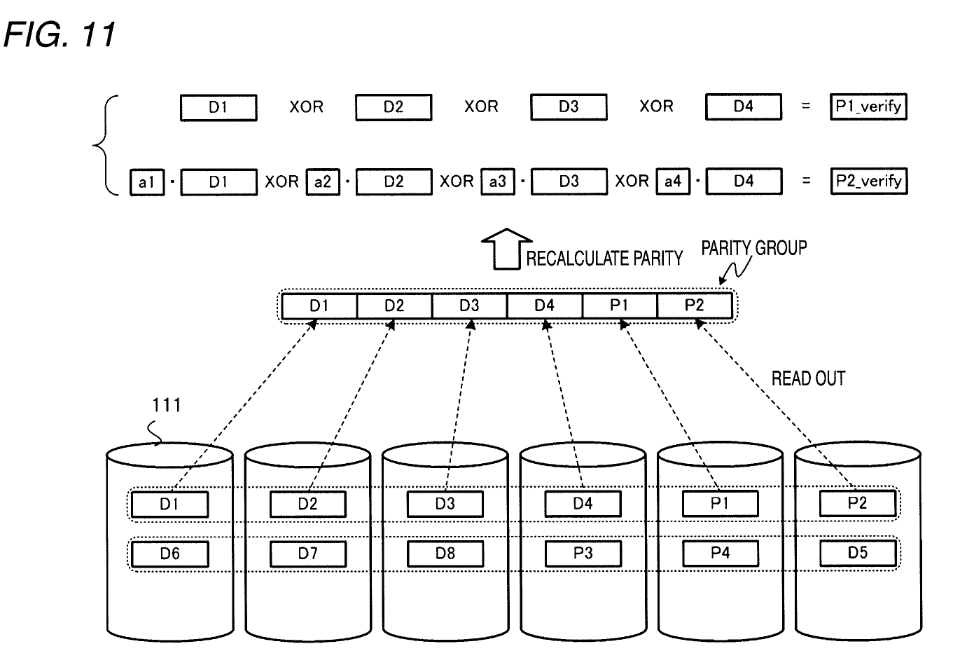

FIG. 11 is a conceptual diagram for explaining a parity check processing by the controller 12 according to an embodiment of the invention. The controller 12 executes the parity check processing independently of a write request from the host computer 3, for example, in the background of an I/O processing or prior to a read processing in response to a read request. The controller 12 performs a data verification due to the parity check processing when the data verification mode is set to the parity check mode. Data to be an object of the parity check processing is a data segment stored in a block area corresponding to a cell which is turned ON in the update data management table 500.

As shown in FIG. 11, a data segment to be an object of the parity check processing is read out from the hard disk drive 111 by the controller 12. In this case, a parity group including the data segment is read out under the RAID control. The parity group read out from the hard disk drives 111 is written into the memory unit 125. Then, based on the data segment included in the read parity group, the first and second parities are recalculated, which are compared with the read first and second parities, respectively. As a result, when the first parities and the second parities respectively do not coincide with each other, any of the data segments has abnormality. Therefore, any of the parities is used to specify an abnormal data segment (that is, the hard disk drive 111 storing the abnormal data segment).

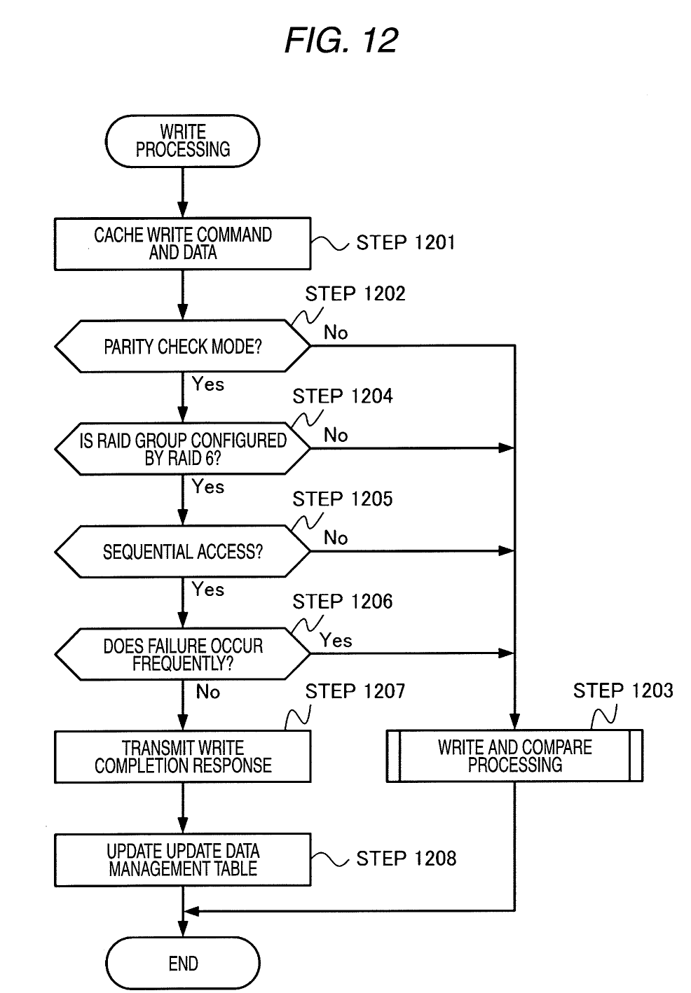

FIG. 12 is a flowchart for explaining a data write processing by the controller 12 according to an embodiment of the invention.

When receiving a write command transmitted from the host computer 3, the controller 12 caches data associated with the write command (STEP 1201). More specifically, when receiving a write command transmitted from the host computer 3, the host interface 121 writes the write command and data associated with the same into a predetermined cache area in the memory unit 125 via the data controller 122.

When the write command and the data are written into the memory unit 125, the controller 12 refers to the data verification mode definition table 600 to determine whether or not the data verification mode is set to the parity check mode (STEP 1202). Specifically, it is determined whether a RAID group forming a logical unit designated as an access destination (access object) by the write command is in the write and compare mode or in the parity check mode.

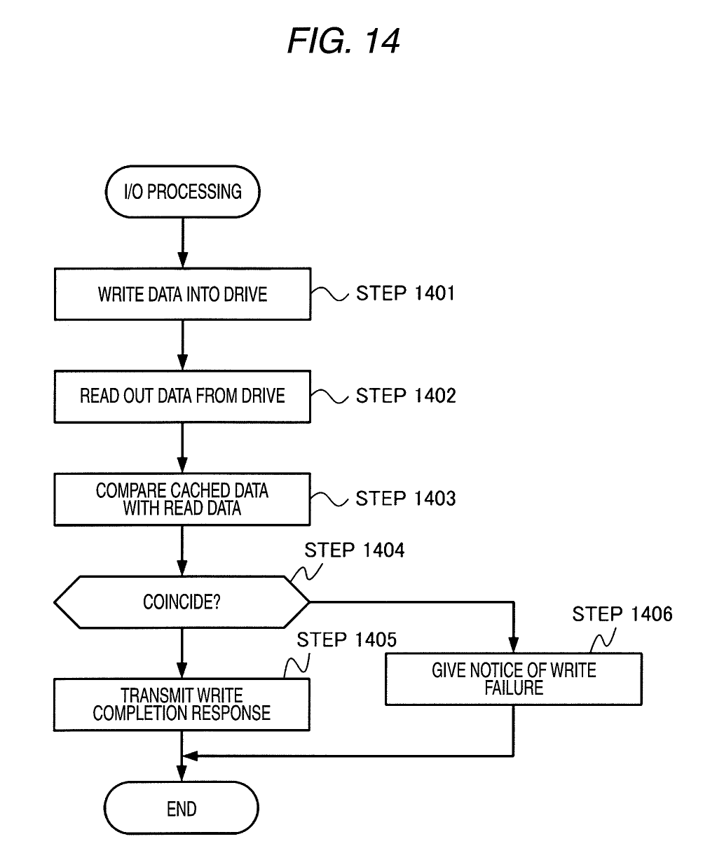

When determining that the data verification mode of the RAID group as an access destination is not the parity check mode (No in STEP 1202), the controller 12 executes the write and compare processing (STEP 1203). The detail of the write and compare processing will be described using FIG. 14.

Whereas, when determining that the RAID group forming the logical unit as an access destination is in the parity check mode (Yes in STEP 1202), the controller 12 subsequently performs branch determinations in accordance with predetermined additional conditions (STEP 1204 to STEP 1206). In the embodiment, the setting of the predetermined additional conditions enables a more fine-grained system control, which is preferable. However, they are not essential and may be properly set as needed. In accordance with a result of determination of the predetermined additional conditions, the controller 12 executes the write and compare processing even under the parity check mode. Specifically, the controller 12 first determines whether or not the relevant RAID group is configured by RAID 6 (STEP 1204). When determining that the RAID group is not configured by RAID 6 (No in STEP 1204), the controller 12 executes the write and compare processing (STEP 1203). On the other hand, when determining that the RAID group is configured by RAID 6 (Yes in STEP 1204), the controller 12 then determines whether or not the relevant write command shows a sequential access pattern (STEP 1205).

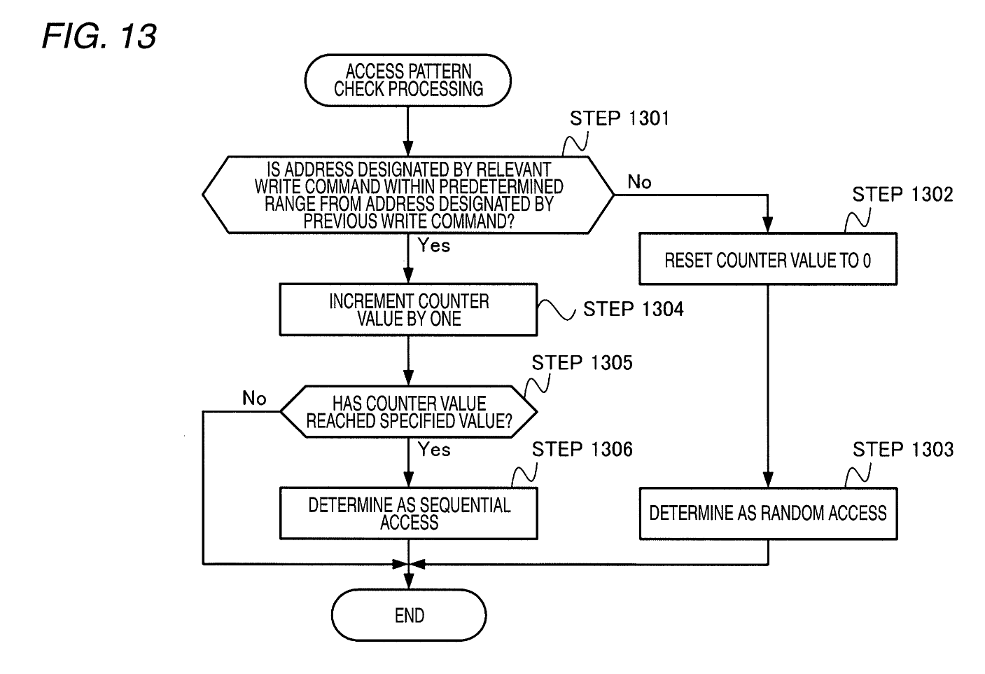

FIG. 13 is a flowchart for explaining an access pattern check processing by the controller 12 according to an embodiment of the invention. The access pattern check processing is a processing for checking whether a series of write commands can be assumed as a sequential access or as a random access.

In the access pattern check processing, the controller 12 determines whether or not an address designated by the newest write command is within a predetermined range from an address designated by the previous write command (STEP 1301). When determining that the address designated by the newest write command is not within a predetermined range from the address designated by the previous write command (No in STEP 1301), the controller 12 resets the value of counter to “0” (STEP 1302) as well as determines that the relevant write command is a random access (STEP 1303).

Whereas, When determining that the address designated by the newest write command is within a predetermined range from the address designated by the previous write command (Yes in STEP 1301), the controller 12 increments the value of counter by one (STEP 1304) and determines whether or not the relevant value of counter has reached a specified value (STEP 1305). When determining that the relevant value of counter has reached a specified value (Yes in STEP 1305), the controller 12 determines that the relevant write command is a sequential access (STEP 1306). On the other hand, when determining that the relevant value of counter has not reached a specified value (No in STEP 1305), the controller 12 waits for the next write command to check the access pattern.

As described above, when certain sequentiality is found in the addresses designated by a series of write commands, the controller 12 determines that a sequential access is being carried out.

Returning to FIG. 12, when determining that the relevant write command request is not a sequential access (No in STEP 1205), the controller 12 executes the write and compare processing (STEP 1203). On the other hand, when determining that the write command is a sequential access (Yes in STEP 1205), the controller 12 subsequently determines whether or not failure tends to occur frequently in the hard disk drive 111 as a write destination designated by the relevant write command (STEP 1206). That is, the controller 12 refers to the drive failure management table 800 shown in FIG. 8 to determine whether or not any of the error items 801 exceeds a predetermined threshold value.

As a result, when determining that failure tends to occur frequently (Yes in STEP 1206), the controller 12 executes the write and compare processing (STEP 1203). This is because since failure tends to occur frequently in the hard disk drive 111, importance is attached to ensuring reliability even at the expense of lowering processing performance.

When determining that failure does not tend to occur frequently (No in STEP 1206), the controller 12 transmits a write completion response to the host computer 3 in response to the write command (STEP 1207). In this case, data associated with the write command has not yet stored in the hard disk drives 111. In the embodiment, however, a write completion response is transmitted to the host computer 3 at the time when the data is written into a cache area from the viewpoint of response performance. The data written into the cache area is written (destaged) into the hard disk drives 111 at a predetermined timing.

The controller 12 sets a bit to “1” in the update data management table 500 corresponding to the storage area on the hard disk drive 111 designated by the write command (STEP 1208). The controller 12 refers to the update data management table 500 thus updated to execute the parity check processing independently of the write processing.

FIG. 14 is a flowchart for explaining the write and compare processing by the controller 12 according to an embodiment of the invention.

As shown in FIG. 14, in the write and compare processing, the controller 12 first stores data written into a cache area into predetermined storage areas on the hard disk drives 111 under the RAID control (STEP 1401). That is, in the case of RAID 6, a parity group including data segments and two parities is stored in the hard disk drives 111 in a striping fashion. Subsequently, the controller 12 reads out the just stored data from the hard disk drives 111 to write the same into a work area in the memory unit 125 (STEP 1402).

Next, the controller 12 compares the data written into the cache area with the data read out from the hard disk drives 111 (STEP 1403) to determine whether or not they coincide with each other (STEP 1404).

As a result of the comparison, when determining that they coincide with each other (Yes in STEP 1404), the controller 12 transmits a write completion response to the host computer 3 (STEP 1405). On the other hand, as a result of the comparison, when determining that the contents of them do not coincide with each other (No in STEP 1404), the controller 12 transmits a write failure response to the host computer 3 (STEP 1406). When receiving the write failure response, the host computer 3 transmits a write request again to the controller 12.

Even when it is determined that they do not coincide with each other, the data still remains in the cache area. Therefore, the controller 12 may not immediately transmit a write failure response to the host computer 3 but may write again the data in the cache area into predetermined storage areas on the hard disk drives 111 and read out to compare them. When they do not coincide with each other even after retrying a predetermined number of times, the controller 12 transmits a write failure response to the host computer 3.

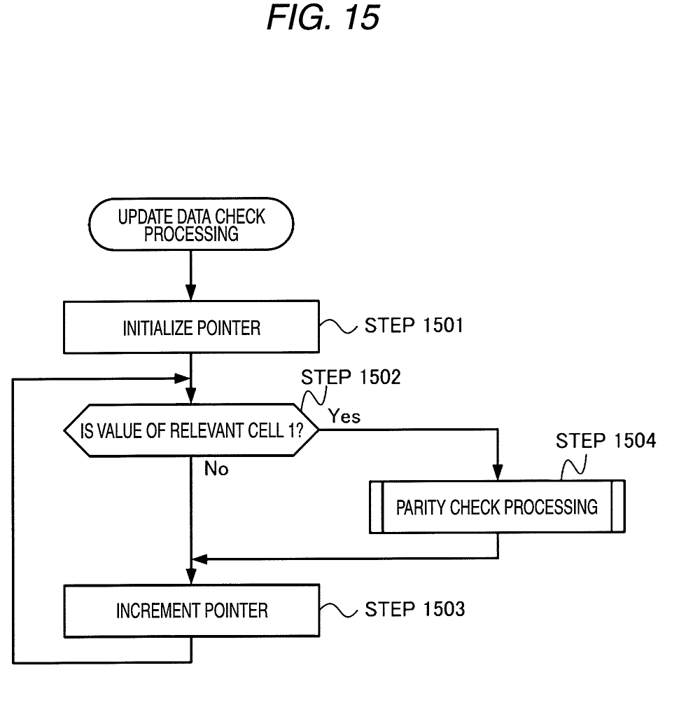

FIG. 15 is a flowchart for explaining an update data check processing by the controller 12 according to an embodiment of the invention. The update data check processing is executed independently of a normal write processing in response to a write request, for example, in the background. Therefore, even when numerous write requests to the storage subsystem 1 occur, and the system load is temporarily high, the system resources can be concentrated on the write processing, thereby being capable of suppressing deterioration of processing performance.

Referring to FIG. 15, prior to checking whether or not data has been updated on the hard disk drives 111, the controller 12 initializes the value of pointer so that a pointer indicates a leading cell in the update data management table 500 (STEP 1501).

The controller 12 determines whether or not the value of a cell in the update data management table 500 indicated by the pointer is “1” (STEP 1502). When the value of the cell is not “1” (No in STEP 1502), the controller 12 increments the value of pointer by one (STEP 1503).

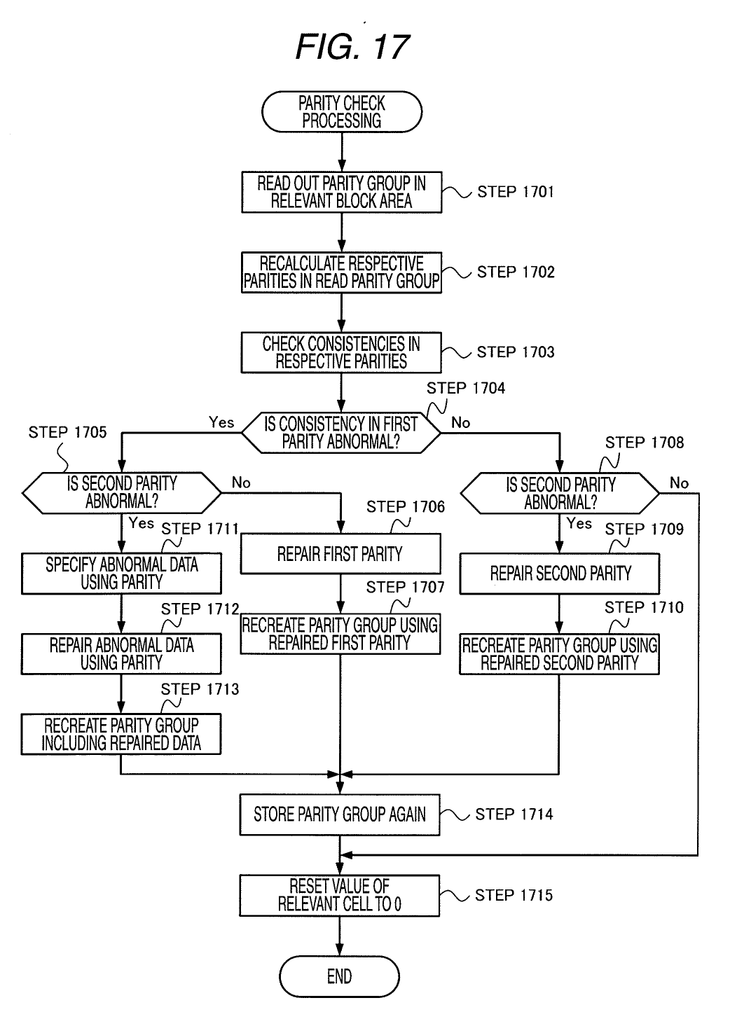

On the other hand, when determining that the value of the cell in the update data management table 500 indicated by the pointer is “1” (Yes in STEP 1502), the controller 12 proceeds to the execution of the parity check processing (STEP 1504). The detail of the parity check processing will be described using FIG. 17. When the validity of data is verified by the parity check processing, the value of the corresponding cell is reset to “0”.

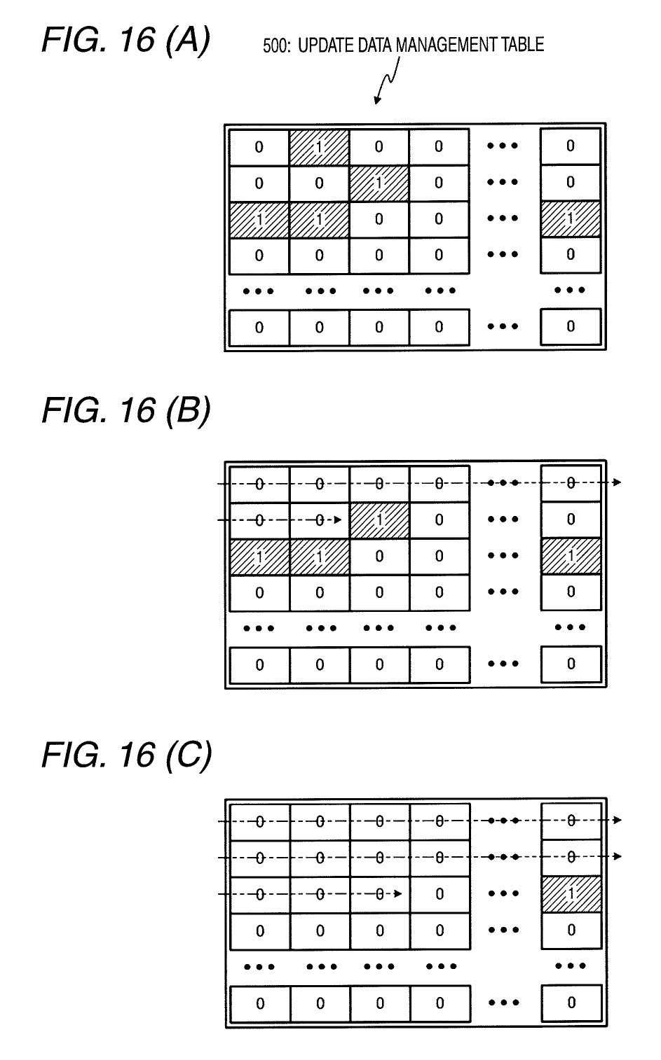

FIGS. 16A to 16C show the transition of the content of the update data management table 500 in the update data check processing. First, the content of the update data management table 500 is assumed to be in a state shown in FIG. 16A. The controller 12 scans the update data management table 500 in accordance with the value of pointer to find a cell having a value of “1” (FIG. 16B). The cell having a value of “1” indicates that data in a corresponding block area has been updated. When finding the cell having a value of “1”, the controller 12 executes the parity check processing. As a result, when determining that the data is valid, the controller 12 resets the value of the cell to “0” to continue scanning (FIG. 16C). When the scanning reaches the last cell in the update data management table 500, the controller 12 returns to the leading cell. In this way, the controller 12 checks the presence or absence of data which has been updated but not yet checked with parity independently of an I/O processing. When such data is found, the controller 12 executes the parity check processing to verify the validity of the data.

FIG. 17 is a flowchart for explaining the parity check processing by the controller 12 according to an embodiment of the invention.

Referring to FIG. 17, the controller 12 reads out a parity group (that is, a data set including data segments and the parities) to which data in a block area corresponding to the relevant cell belongs from the hard disk drives (STEP 1701). The read parity group is written into a work area in the memory unit 125.

Subsequently, the controller 12 recalculates the first and second parities for verification based on a data segment belonging to the parity group (STEP 1702) and compares the first and second parities of the read parity group with the recalculated first and second parities for verification, respectively, to check consistency in parity (STEP 1703). That is, the consistency between the first parity and the first parity for verification and the consistency between the second parity and the second parity for verification are checked.

As a result, when determining that there is no abnormality in consistency of the first parity (No in STEP 1704), and that there is no abnormality also in consistency of the second parity (No in STEP 1708), the controller 12 resets the value of the relevant cell to “0” because there is no contradiction in the data segment belonging to the parity group, and it can be said that the data is valid (STEP 1715).

Whereas, when determining that there is an abnormality in consistency of the first parity (Yes in STEP 1704), but that there is no abnormality in consistency of the second parity (No in STEP 1705), the controller 12 repairs the first parity because only the read first parity is abnormal (STEP 1706) and recreates a parity group using the repaired first parity (STEP 1707). Then, the controller 12 stores the recreated parity group in the hard disk drives 111 (STEP 1714) and resets the value of the relevant cell to “0” (STEP 1715).

Further, when determining that there is no abnormality in consistency of the first parity (No in STEP 1704), but that there is an abnormality in consistency of the second parity (Yes in STEP 1708), the controller 12 repairs the second parity because only the read second parity is abnormal (STEP 1709) and recreates a parity group using the repaired second parity (STEP 1710). Then, the controller 12 stores the recreated parity group in the hard disk drives 111 (STEP 1714) and resets the value of the relevant cell to “0” (STEP 1715).

Further, when determining that there is an abnormality in consistency of the first parity (Yes in STEP 1704), and that there is an abnormality also in consistency of the second parity (Yes in STEP 1705), the controller 12 repairs the data segment as follows because both of the read first and second parities are abnormal.

That is, when determining that there is an abnormality in consistency of both of the read first and second parities, the controller 12 specifies an abnormal data segment (that is, the hard disk drive 111 in which a write error has occurred) using the data segments and two parities in the parity group (STEP 1711). Specifically, the abnormal data segment is specified by solving binary simultaneous equations using equations by which the first and second parities are calculated.

When the abnormal data segment is specified, the controller 12 next repairs the abnormal data segment using at least one of the parities (STEP 1712). Specifically, a new data segment to be stored in the hard disk drive 111 in which a write error has occurred is reproduced using the parity. The controller 12 creates a new parity group including the repaired data segment (STEP 1713) and stores the same in the hard disk drives 111 (STEP 1714). Then, the controller 12 resets the value of the relevant cell to “0” (STEP 1715).

As described above, the hard disk drive 111 in which a write error has occurred can be specified using the first and second parities, and the data segment to be stored in the hard disk drive 111 in which the error has occurred can be repaired. Therefore, the reliability is further improved.

The repair of data has been described on the assumption that a write error has occurred in one of the hard disk drives 111 (one data segment is abnormal in a parity group). However, it is extremely rare that a write error simultaneously occurs in two of the hard disk drives 111. Therefore, a person skilled in the art will appreciated that the above repair of data is sufficient for practical use.

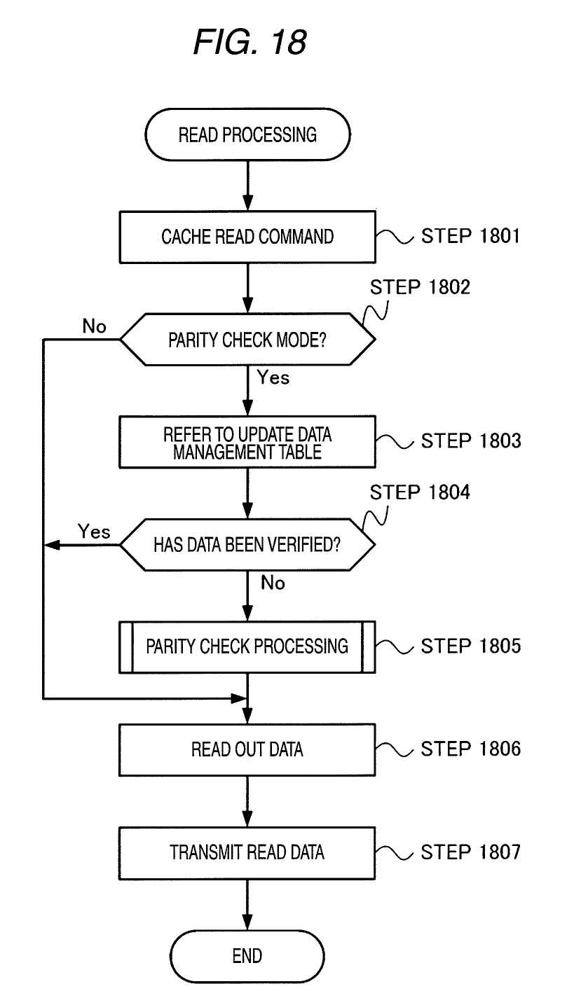

FIG. 18 is a flowchart for explaining a read processing by the controller 12 according to an embodiment of the invention.

When receiving a read command transmitted from the host computer 3, the controller 12 writes the read command into a cache area in the memory unit 125 (STEP 1801).

When the read command is written into the memory unit 125, the controller 12 next refers to the data verification mode definition table 600 to determine whether or not the data verification mode 602 is set to the parity check mode (STEP 1802). Specifically, it is determined whether a RAID group forming a logical unit designated as an access destination by the read command is in the write and compare mode or in the parity check mode.

When determining that the data verification mode of the RAID group as an access destination is not set to the parity check mode (No in STEP 1802), the controller 12 reads out data from storage areas on the hard disk drives 111 designated by the read command in the same manner as in a normal read processing (STEP 1806) and transmits the read data to the host computer 3 as a response to the read command (STEP 1807).

Whereas, when determining that the data verification mode 602 is set to the parity check mode (Yes in STEP 1802), the controller 12 refers to the update data management table 500 (STEP 1803) to determine whether or not the data stored in a block area including storage areas on the hard disk drives 111 designated by the read command has been verified (STEP 1804). That is, it is determined whether or not the value of a cell in the update data management table 500 corresponding to the block area including the storage areas on the hard disk drives 111 designated by the read command is “0”.

When determining that the data has not yet been verified (No in STEP 1804), the controller 12 performs the parity check processing described above (STEP 1805). As a result, when the validity of data is confirmed, the controller 12 reads out data from the storage areas on the hard disk drives 111 designated by the read command (STEP 1806). However, since the data has already been read out from the storage areas on the hard disk drives 111 in the parity check processing, the controller 12 may omit a second data read from the viewpoint of processing performance.

On the other hand, when determining that the data has been verified (Yes in STEP 1804), the controller 12 reads out the data from the storage areas on the hard disk drives 111 designated by the read command without performing the parity check processing (STEP 1806).

The controller 12 then transmits the read data to the host computer 3 as a response to the read command (STEP 1807).

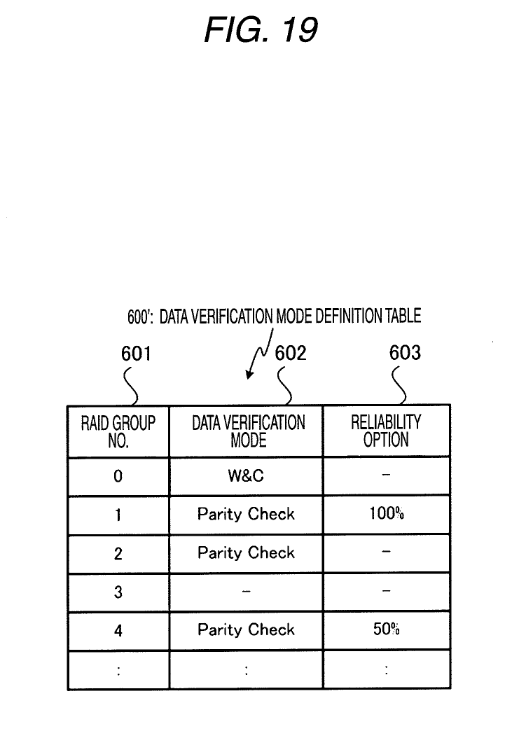

As a modified example of the above read processing, reliability option may be introduced in the data verification mode. The reliability option is a ratio for executing the parity check processing at the time of response due to a read command. FIG. 19 shows a data verification mode definition table 600′ of the example. As shown in FIG. 19, the data verification mode definition table 600′ of the example includes reliability option 603. Although FIG. 19 shows an example of the data verification mode definition table 600′ with a RAID group being as an access object, the data verification mode definition table 600′ with a logical unit or a drive unit (chassis) being as an access object can be understood similarly. The system administrator can operate the management console 4 to set any value to the reliability option 603. The controller 12 executes the parity check processing once per two responses to read command for RAID group #4 in which the reliability option 603 is set to 50%. For example, the controller 12 holds history information of read command in a work area in the memory unit 125.

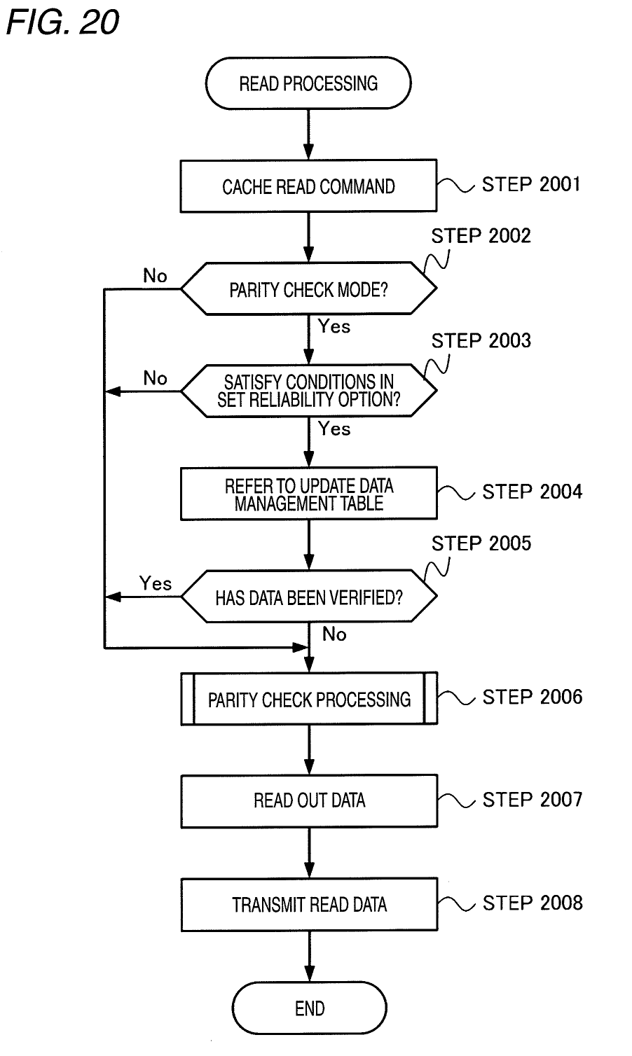

FIG. 20 is a flowchart for explaining the read processing of the example. FIG. 20 is the same as the flowchart as shown in FIG. 18 except that a check processing in STEP 2003 is added. That is, when determining that the data verification mode 602 is set to the parity check mode (Yes in STEP 2002), the controller 12 further determines whether or not the reliability option 603 is set (STEP 2003). When determining that the reliability option 603 is set, and that the ratio shown in the reliability option 603 is satisfied (Yes in STEP 2003), the controller 12 moves the processing to STEP 2004 and subsequent steps. Since the processings in STEP 2004 and subsequent steps are similar to those in STEP 1803 and subsequent steps described above, the description thereof is omitted.

As described above, according to the embodiment, a storage subsystem meeting the demand for reliability and having a high processing performance is provided since data stored in a hard disk drive is verified independently of a response to a write request.

Further, according to the embodiment, even when abnormality is found in data by the data verification, the abnormal data can be repaired by using parity. Therefore, reliability equivalent to that of a conventional data verification method can be assured even without performing the data verification in each write request. Accordingly, even the SATA drive, which is low in reliability in a single unit, can be employed for a storage subsystem for which high reliability is demanded, so that the manufacturing cost can be suppressed low.

Especially, the SATA drive is frequently used for archives from the viewpoint of cost or the like. In the archives, writing pattern of data is liable to be a sequential access in general. Accordingly, overhead due to the read of parity is small compared with the case where the writing pattern of data is a random access. Therefore, the embodiment is especially effective for a data verification at the time of writing data due to a sequential access.

The above embodiment is an exemplification for explaining the invention, and it is not intended to limit the invention only to the above embodiment. The invention can be carried out in various forms as long as not departing from the gist of the invention. For example, although the processing of various programs has been described sequentially in the above embodiment, the invention is not especially limited thereto. Accordingly, the processing may be changed in order or operated in parallel as long as no contradiction arises in the processing result.

What is claimed is:

1. A storage subsystem comprising:
a storage device formed with at least one virtual device based on at least one hard disk drive; and
a controller connected to the storage device for controlling an access to a corresponding virtual device of the storage device in response to a predetermined access command transmitted from a host computer, wherein
the controller calculates, in response to a write command transmitted from the host computer, at least one parity based on a data segment associated with the write command and stores a data set including the data segment and the calculated at least one parity into storage areas in the virtual device in a striping fashion; and
the controller performs a parity check processing which reads out the data set from the storage areas in the virtual device, calculates at least one parity for verification based on a data segment in the read data set and determines, based on the calculated at least one parity for verification and the at least one parity in the read data set, whether or not there is an abnormality in consistency of the at least one parity.

2. A storage subsystem according to claim 1, wherein
the controller performs the parity check processing independently of a response to the write command.

3. A storage subsystem according to claim 1, wherein
the controller performs the parity check processing in response to a read command transmitted from the host computer.

4. A storage subsystem according to claim 1, wherein
when determining that there is an abnormality in consistency of the at least one parity, the controller specifies an abnormal data segment in the data set based on the at least one parity in the read data set.

5. A storage subsystem according to claim 4, wherein
the data set includes first and second parities; and
when determining that there is an abnormality both in consistency of the first parity and in consistency of the second parity, the controller specifies an abnormal data segment in the data set based on the first and second parities and repairs the specified abnormal data segment.

6. A storage subsystem according to claim 1, wherein
the controller includes an update data management table for managing whether or not a data segment stored in a storage area in the virtual device has been updated;
when determining that a data segment stored in a specific storage area has been updated based on the update data management table, the controller reads out a data set including the data segment stored in the specific storage area from the virtual device in order to perform the parity check processing.

7. A storage subsystem according to claim 6, wherein
the controller sets a value of a cell in the update data management table corresponding to the storage area to ON at the time point of writing the data set into storage areas in the virtual device in response to the write command; and
the controller checks a value of each cell in the update data management table to specify a storage area on which the parity check processing is to be performed.

8. A storage subsystem according to claim 1, wherein
the controller includes a data verification mode definition table for defining a data verification mode for the virtual device.

9. A storage subsystem according to claim 8, wherein
when a specific data verification mode is set for the virtual device in the data verification mode definition table, the controller caches a data segment associated with the write command in response to the write command and thereafter, stores the data set based on the data segment in storage areas in the virtual device in a striping fashion as well as reads out the data segment in the stored data set from the storage area in the virtual device and verifies the validity of the data segment stored in the storage area in the virtual device based on the cached data segment and the read data segment.

10. A storage subsystem comprising:
a storage device formed with at least one virtual device based on at least one hard disk drive; and
a controller connected to the storage device for controlling an access to a corresponding virtual device of the storage device in response to a predetermined access command transmitted from a host computer, wherein
the controller calculates, in response to a write command transmitted from the host computer, at least one parity based on a data segment associated with the write command and stores a data set including the data segment and the calculated at least one parity into storage areas in the virtual device in a striping fashion; and
when a first data verification mode is set for an access object designated by the write command, the controller performs a first data verification processing for verifying a data segment stored in a storage area in the virtual device at the time of response to the write command, and when a second data verification mode is set for the access object designated by the write command, the controller performs a second data verification processing for verifying the data segment stored in the storage area in the virtual device independently of a response to the write command.

11. A storage subsystem according to claim 10, wherein
the controller caches the data segment associated with the write command in response to the write command in the first data verification processing and thereafter, stores the data set based on the data segment in storage areas in the virtual device in a striping fashion as well as reads out the data segment in the stored data set from the storage area in the virtual device and verifies the validity of the data segment stored in the storage area in the virtual device based on the cached data segment and the read data segment.

12. A storage subsystem according to claim 10, wherein
when the second data verification mode is set for an access destination designated by the write command in the second data verification processing, the controller reads out the data set stored in the storage areas in the virtual device in a striping fashion, calculates at least one parity for verification based on a data segment in the read data set and verifies the validity of the data segment stored in the storage area in the virtual device based on the calculated at least one parity for verification and at least one parity in the read data set.

13. A storage subsystem according to claim 10, wherein
the controller performs the second data verification processing in response to a read command transmitted from the host computer.

14. A storage subsystem according to claim 10, wherein
when determining that the write command shows a sequential access pattern, the controller performs the second data verification processing.

15. A storage subsystem according to claim 10, wherein
the controller includes a failure management table for managing error information for each of the plurality of hard disk drives forming the virtual device; and
when failure which occurs in the plurality of hard disk drives exceeds a predetermined permissible value, the controller performs the first data verification processing in accordance with the failure management table.

16. A method for verifying data in a storage subsystem, the storage subsystem including a storage device formed with at least one virtual device based on at least one hard disk drive and a controller connected to the storage device for controlling an access to a corresponding virtual device of the storage device in response to a predetermined access command transmitted from a host computer, the method comprising the steps of:
receiving, by the controller, a write command transmitted from the host computer;
calculating, by the controller, in response to the received write command, at least one parity based on a data segment associated with the write command and storing a data set including the data segment and the calculated at least one parity into storage areas in the virtual device in a striping fashion; and
performing, by the controller, a parity check processing which reads out the data set from the storage areas in the virtual device independently of a response to the write command, calculates at least one parity for verification based on the data segment in the read data set and determines, based on the calculated at least one parity for verification and the at least one parity in the read data set, whether or not there is an abnormality in consistency of the at least one parity.
